(19) United States
(12) Patent Application Publication
(10) Pub. No.: US 2019/0019776 A1
(43) Pub. Date: Jan. 17, 2019

(54) STRUCTURES AND METHODS FOR CAPACITIVE ISOLATION DEVICES

(71) Applicant: Texas Instruments Incorporated, Dallas, TX (US)

(72) Inventors: Enis Tuncer, Dallas, TX (US); Minhong Mi, Newton, MA (US); Swaminathan Sankaran, Allen, TX (US); Rajen M. Murugan, Garland, TX (US); Vikas Gupta, Dallas, TX (US)

(21) Appl. No.: 15/646,976

(22) Filed: Jul. 11, 2017

(51) Int. Cl. H01L 25/065; H01L 23/31; H01L 49/02; H01L 23/495; H01L 23/00

(52) U.S. Cl. CPC H01L 25/0655; H01L 23/3157; H01L 28/40; H01L 23/49555; H01L 23/4952; H01L 2224/05647; H01L 24/14; H01L 24/46; H01L 2224/04042; H01L 2224/85; H01L 2224/05624; H01L 24/06

(57) ABSTRACT

Described examples include a packaged device including a first object and a second object spaced from each other by a gap, each object having a first surface and an opposite second surface, the first surfaces of the first object and the second object including first terminals. A structure includes at least two conductors embedded in a dielectric casing consolidating a configuration and organization of the at least two conductors, the at least two conductors having end portions un-embedded by the dielectric casing. An end portion of at least one of the at least two conductors is electrically connected to a first terminal of the first object, and an opposite end portion of the at least one of the at least two conductors is electrically connected to a respective first terminal of the second object, the at least two conductors electrically connecting the first object and the second object.

### TECHNICAL FIELD

This relates in general to the field of semiconductor devices and processes, and more specifically to the structure and fabrication method of semiconductor devices.

### BACKGROUND

Two commonly used methods for connecting device terminals of semiconductor dies to substrates are wire bonding and flip-chip solder attachment. In wire bonding, an elongated metal wire has a ball bond on one wire end and a stitch bond on the opposite wire end. In wire bonding technology, round wires of copper, gold or aluminum and of about 18 μm to 33 μm diameter are used.

While bonding wire metals can be stiffened by alloying with other metals, in use bonding wires are subject to sagging under their own weight, especially in bond wires spanning long die-to-substrate or die-to-die distances. Sagging bond wires, in turn, change loop profiles, especially bends and kinks.

In addition, bond wire loops are sometimes swept sidewise under mechanical pressure in follow-up processing such as the transfer molding operations performed to encapsulate dies in plastic packages. Wire sweep changes electrical characteristics and even causes shorts between neighboring bond wires. Molding operations can also modify bond wire loop profiles and die-to-wire distances. Improvements are therefore desired.

### SUMMARY

In a described example, a packaged device includes a first object and a second object spaced from each other by a gap, each object having a first surface and an opposite second surface, the first surfaces of the first object and the second object including first terminals. A structure includes at least two conductors embedded in a dielectric casing consolidating a configuration and organization of the at least two conductors, the at least two conductors having end portions un-embedded by the dielectric casing. An end portion of at least one of the at least two conductors is soldered to a first terminal of the first object, and an opposite end portion of the at least one of the at least two conductors is soldered to a respective first terminal of the second object, the at least two conductors electrically connecting the first object and the second object. In another described example, the packaged device is a digital isolator with a first semiconductor die serving as a modulator, a second semiconductor die serving as a receiver, and a plurality of isolation capacitors with the embedded conductors serving as tuned transmission lines.

### BRIEF DESCRIPTION OF THE DRAWINGS

FIG. 1 is a cross section of an example arrangement including a structure with pre-formed conductors embedded in a dielectric.

FIG. 2 is a cross section of another example arrangement having a first integrated circuit die, a separate first capacitor, and a second integrated circuit die with merged second capacitor interconnected by pre-formed conductors embedded in a dielectric casing.

FIG. 3 is a cross section of a high-speed isolator employing an arrangement of pre-formed conductors embedded in a dielectric casing to couple isolated integrated circuit dies separated by a gap.

FIG. 4 is a cross section of yet another arrangement with a structure including pre-formed conductors embedded in a dielectric casing, in which a first and a second semiconductor die are soldered to the conductors by flip-chip technology and the structure is embedded in a laminated substrate.

FIG. 5 is a cross section detailing the solder attachment an arrangement of pre-formed conductors embedded in a dielectric casing to die terminals with copper pillars.

FIG. 6 is a flow diagram of an example process flow for creating a structure containing pre-formed conductors embedded in a dielectric casing.

FIG. 7 is a flow diagram of another example process flow for connecting a first and a second integrated circuit die by a structure containing an organized plurality of pre-formed conductors embedded in a dielectric casing.

FIG. 8 is a perspective view of a high-speed digital isolator assembled on a leadframe and employing a transmission line structure with an organized plurality of pre-formed conductors interconnecting modulator and receiver dies.

FIG. 9A is a plot of modeling data for insertion loss S₁₁ (in dB) as a function of frequency (in GHz).

FIG. 9B is a plot of modeling data for insertion loss S₂₁ (in dB) as a function of frequency (in GHz).

FIG. 10 is a plot of experimental data for insertion loss (in dB) as a function of frequency (in GHz).

### DETAILED DESCRIPTION

Corresponding numerals and symbols in the different figures generally refer to corresponding parts unless otherwise indicated. The figures are not necessarily drawn to scale.

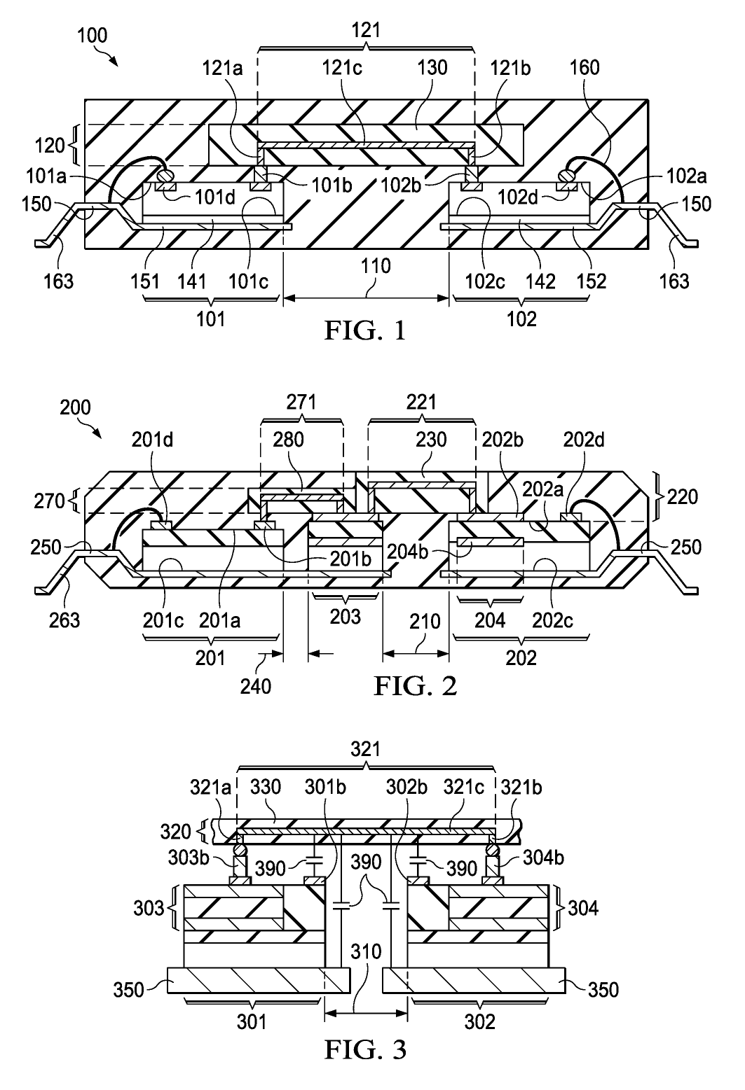

FIG. 1 is a cross section of an example arrangement 100 that includes a first object 101 and a second object 102 spaced apart from each other by a gap 110. Each object has a first surface and an opposite second surface. In FIG. 1, the first surface of object 101 is designated 101a and the opposite second surface is designated 101c; the first surface of the second object 102 is 102a, and the second surface of the second object is 102c. In an example, the objects may be semiconductor dies. In alternative examples, the objects 101 and 102 may be solid hexahedron-shaped carriers made of laminated plastic. The objects may be sensitive to electrical, magnetic, or optical influences.

As FIG. 1 further shows, the first surfaces of object 101 and object 102 include first terminals: first surface 101a includes first terminal 101b, and first surface 102a includes terminal 102b. The terminals 101b, 102b may include solderable metallurgy on the terminals. As examples, the first terminals 101b and 102b may include a pad of copper with a surface of tin, or nickel/palladium, or nickel/palladium/gold. Electroless nickel immersion gold (ENIG) and electroless nickel electroless palladium immersion gold (ENEPIG) platings can form the solderable metallurgy. (FIG. 5 and the accompanying text hereinbelow describes in more detail that in alternative examples the solderable metallurgy can include copper pillars capped by solder. The copper pillars can be vertical columns formed on the terminals and capped by solder.)

The first surfaces of object 101 and 102 include second terminals 101d and 102d, respectively. The second terminals 101d, 102d can include a metallurgy for wire ball bonding. As examples, the second terminals 101d, 102d can include a pad of aluminum, or a pad of copper with a surface of aluminum. The second terminals can include additional coatings (not shown) compatible with wire bonding.

Device 100 includes a structure 120, which is a pre-fabricated piece part composed of a plurality of electrical conductors 121 embedded in a casing 130 that is made of electrically non-conducting, e.g. dielectric, material. The conductors 121 are an electrically conducting material such as metals like copper, copper alloys, or alternatively, carbon nanotubes. The conductors 121 can be formed as wires or as conductive strips. As FIG. 1 indicates, each conductor 121 can appear as a U-shape in a cross sectional view. In FIG. 1, the conductors include a middle section 121c, a first extension section 121a and a second extension section 121b. While the middle section 121c is elongated and straight in this example, the first extension section 121a and the second extension section 121b each form an angle with the middle section. As an example, the first and second extension sections 121a and 121b may form right angles with the middle section 121c. In FIG. 1 the extension sections 121a, 121b form the same angle with the middle section, and extend away from the middle section 121c in the same direction, so that in this example the first extension section 121a and the second extension section 121b are arranged in parallel with respect to one another. In an alternative example the first extension section 121a and the second extension 121b can intersect the middle section 121c at different angles, and can extend from the middle section 121c in different directions. The extension sections 121a, 121b further include end portions (not visible in FIG. 1, but contacting objects 101 at 101b and 102 at 102b), which are un-embedded by the casing 130. In an example, the end portions of the extension sections 121a, 121b can include solderable metallurgy. (The solder attachment of the extension section end portions to first terminals of the objects 101 and 102 is further described hereinbelow in conjunction with the description of FIG. 5). The end portions of the extension sections 121a, 121b of conductor 121 are exposed from the dielectric material of casing 130 to enable electrical and mechanical connections to be made. The end portions of the extension sections 121a, 121b are coplanar with a surface of the casing 130.

In an example arrangement, the casing 130 of structure 120 is made of an electrically isolating dielectric polymeric compound, which is elastic yet capable of consolidating, or “freezing,” the conductors during the embedding process (see further detail hereinbelow). As a consequence, the configuration of each discrete conductor such as 121, as well as the organization of a plurality of conductors within structure 120, are permanently fixed and are not changed by consecutive processes such as transfer molding for forming a device package. The conductors can be arranged with equal spacing and aligned in the same direction to form a plurality of parallel conductors. In alternative examples, the conductors can be spaced at a variety of distances and can be organized and fixed in position without being parallel to one another.

In FIG. 1, device 100 further includes a substrate 150, which includes a metallic pad 151 onto which the second surface 101c of first object 101 can be attached, for instance by adhesive layer 141. In addition, the substrate 150 offers a metallic pad 152 onto which the second surface 102c of second object 102 can be attached, for instance by adhesive layer 142. The substrate 150 also provides a plurality of leads 163 needed for connections of terminals of device 100 to external entities. Pads 151 and 152 may be portions of substrate 150 which can be a leadframe with leads 163.

As FIG. 1 shows, objects 101 and 102 further include second terminals 101d and 102d that are suitable for wire ball bonding. In example the second terminals 101d and 102d include metallurgy for wire bonding. For object 101, a second terminal is designated 101d and is located on first surface 101a. For object 102, a second terminal is designated 102d and is located on first surface 102a. For copper wire bonding and for gold wire bonding, a suitable metallization of the second terminals includes aluminum. Wire loops 160 formed by the wire bonding process connect the second terminals 101d, 102d with leads 163 of the substrate 150 for connections to external entities.

To form the wire bonds such as shown in FIG. 1, the wire bonding process begins by positioning a semiconductor chip on a heated pedestal to raise the temperature to between 150° C. and 300° C. Using an automated wire bonder, the bond wire is strung through a capillary and at the tip of the wire, a free air ball is created using either a flame or a spark technique. The ball has a typical diameter from about 1.2 to 1.6 wire diameters. The capillary is moved towards the die bonding pad and the ball is pressed against the metallization of the pad. A combination of compression force and ultrasonic energy creates metal interdiffusion or metal intermetallics, dependent on the metals of ball and pad, and forms a strong metallurgical bond. Next, the capillary moves vertically upward to accommodate the mechanically weak heat-affected zone in the bond wire at the ball bond. As the capillary moves the wire extends from the ball and pad.

Thereafter, the computerized wire bonder moves the capillary through the air to guide the wire into a pre-determined loop of defined shape including bends, straight stretches, and kinks to span the distance to the substrate bonding pad. The capillary is lowered, sharply bent, and approaches the substrate bonding pad in a glancing angle to touch the pad. With the imprint of the capillary (about 1.5 to 3 times the wire diameter), a metallurgical stitch bond is formed, and the bond wire is then broken off to release the capillary.

It follows from this brief description of materials and process parameters that especially long bond wire loops can be sensitive relative to wire profile and configuration, loop height, wire loop deformations, wire sweep, and relative to coupling between wire bond and dielectric material variation, since these variables affect the electrical performance required for high frequency applications.

Structure 120 with its embedded connectors 121 interconnects several objects by using the end portions of connector 121. FIG. 1 illustrates the interconnection of first object 101 to second object 102, spaced apart from each other by gap 110 (and FIG. 2 and the accompanying text hereinbelow discusses additional interconnections). In FIG. 1, the end portion of extension section 121a of conductor 121 is soldered to a first terminal 101b of first object 101, and the opposite end portion of extension section 121b of conductor 121 is soldered to a respective first terminal 102b of second object 102. After solder attachment, conductor 121 inside structure 120 connects the first object 101 and the second object 102 across the gap 110. Even for gaps 110 extending in the millimeter and centimeter ranges, the connector 121 embedded in structure 120 establishes robust electrical connection of first object 101 and second object 102. In an example, the first object 101 and the second object 102 are semiconductor dies including circuitry. In an alternative example, the first object 101 and the second object 102 can be passive circuit devices.

To illustrate another example arrangement, FIG. 2 is a cross section of a packaged device 200 for a high speed isolator. As described herein, a low frequency signal may be less than 30 MHz, for example. A high frequency signal may be greater than 30 MHz and up to 300 MHz, for example. While for direct current (DC) signals, objects of dielectric material can isolate electrical circuits from other electrical systems, for high frequency signals, isolation of electrical circuits should block low-frequency signals between circuits, but allow high-frequency analog or digital signal transfer by use of electromagnetic or optical links. When considering the efficiency of isolating electrical circuits, the general energy consideration of EQ. 1 holds:

E_{incoming}=E_{reflected}+E_{transmitted}+E_{absorbed} (1)

The energy loss by coupling isolated electrical circuits can be expressed as insertion loss by complementary energy ratios, as in EQ. 2 and EQ. 3:

Insertion loss S₁₁=E_{reflected}/E_{incoming} (2)

Insertion loss S₂₁=E_{transmitted}/E_{incoming} (3)

To transmit information across an isolation barrier, capacitive coupling uses a changing electric field. The material between capacitor plates in the capacitive coupling is a dielectric insulator forming the isolation barrier. The capacitance of the capacitive coupling is characterized by size, distance between the plates, and material properties. Due to their size, energy transfer, and immunity to magnetic fields, capacitive isolation barriers show high efficiency. On the other hand, since noise and signals share the same transmission path, the signal frequencies have to be well above the noise frequency so that capacitance in the capacitive coupling has a relatively low impedance to the signals and a corresponding relatively high impedance to the noise. These signal frequencies are relatively high frequencies.

FIG. 2 is a cross section of an arrangement for a packaged device forming a high-speed isolator 200. In FIG. 2, a first semiconductor integrated circuit die 201 is spaced apart from a separate first capacitor 203 by a gap 240, and first capacitor 203 is spaced apart from a second semiconductor integrated circuit die 202 by a gap 210. In the example in FIG. 2 the gap 210 is greater than gap 240. In alternative arrangements, the first capacitor 203 can be integrated with the first die 201 so that gap 240 does not exist. Integrated with second die 202 is a second capacitor 204 with a terminal 202b; the first capacitor 203 also has a terminal 203b. In an example, the terminal 202b and the terminal 203b of the first capacitor 203 include solderable metallurgy. In additional arrangements, the second capacitor 204 may not be integrated with the second die but instead is separated from the die by a gap. The protective coat of first die 201 has a first surface 201a and the protective coat of the second die 202 has a first surface 202a. The opposite second surface 201c of the first die 201 and the opposite second surface 202c of second die 202 are assembled on a substrate 250. In one example, the substrate 250 is a metallic leadframe with assembly pads for mounting the parts. In an alternative arrangement the substrate 250 can be a conductive adhesive polymeric layer. The leadframe 250 further provides leads 263 for external connections. Semiconductor dies 201 and 202 are commonly silicon, but can be any other semiconductor material such as gallium nitride and gallium arsenide. Epitaxial layers can form the semiconductor material.

In FIG. 2 the first surfaces of first die 201 and second die 202 include first terminals. First surface 201a includes first terminal 201b, and first surface 202a includes first terminal 202b (which can be combined with the capacitor terminal 204b). In an example, the first terminal 201b and the first terminal 202b can include solderable metallurgy. As an example, the first terminals 201b and 202b may include a pad of copper with a surface of tin, or nickel/gold, nickel/palladium, or nickel/palladium/gold. (FIG. 5 and the accompanying text hereinbelow describes in more detail that the solderable metallurgy can further include copper pillars capped by solder. The copper pillars can include vertical pillars extending from the surface of the dies 201, 202 and capped with solder.) In the capacitive isolator of FIG. 2, the first surfaces of first dies 201 and 202 include second terminals 201d and 202d, respectively. The second terminals can include metallurgy suitable for wire ball bonding. As examples, the second terminals 201d, 202d can include a pad of aluminum, or a pad of copper with a surface of aluminum.

As FIG. 2 illustrates, capacitive isolator 200 includes structures (220, 270) with electrical conductors (221, 271 respectively) embedded in dielectric casings (230, 280 respectively) for connecting the parts. In this example, two structures are shown. In alternative arrangements, many structures can be used. The widths of the casings 230 and 280 can be equal, or can be different as shown in FIG. 2. Each conductor 271, 221 has an end portion that is not embedded by the casing. The configuration of each conductor and the organization of a plurality of conductors is fixed (“frozen”) in the dielectric casing of the structures selected so that the structures serve as tuned transmission lines, reducing or minimizing any insertion loss. For a given frequency ω of the transmission signal, the signal integrity can be determined and the transmission line by determining the impedance Z of each conductor from the conductor's resistance R, inductance L, conductance G, and stray capacitance C correlated by the relation of EQ. 4:

Z=[(R+iωL)/(G+iωC)]^{1/2} (4)

EQ. 4 implies that by selecting the geometries, angles, and proximities of the conductors, acceptable stray capacitance values C can be achieved and frozen with regard to the conductor size and distribution by embedding the conductors in the dielectric casing and thus finalizing the structures. The structures can be made as prefabricated parts for assembly with the remaining parts of isolator 200. After assembly of the parts, transfer molding can be used with thermoplastic resin mold compound to form the packaged device 200. In another alternative approach, a room temperature mold compound can be used or other resin or epoxy can be used to form the packaged isolator device 200.

FIG. 3 is a cross section of another arrangement using a capacitive isolator to connect a modulator and receiver. In FIG. 3, a first die (modulator) 301 with its first terminals 301b and the second die (receiver) 302 with its first terminals 302b are spaced by gap 310. Terminals 301b and 302b may or may not have solderable metallurgy. The first capacitor is designated 303, and the second capacitor is designated 304. Both capacitors have terminals (303b and 304b respectively). In an example the terminals can include solderable metallurgy. FIG. 3 indicates a plurality of stray capacitors 390 between the conductors 321 embedded in dielectric casing 330 of a structure 320, and the first die 301, the second die 302, and the substrate 350 supporting the dies.

As stated above, the configuration of the conductors and the positioning of a plurality of conductors inside the dielectric casing of the structures such as 320 keeps stray capacitances within stable and acceptable limits. The process of fabricating the structure with fixed conductors includes the steps of forming conductors 321. As shown in FIG. 3, the conductors can have a U-shape in cross section including a middle section 321c and a first (321a) and a second (321b) extension section connected at an angle with the middle section, the conductors having end portions. A plurality of conductors can be organized by arranging the conductors in an aligned or parallel configuration at predetermined distances; and by consolidating the organized conductors by embedding the conductors in a dielectric compound, while leaving end portions of the conductors un-embedded. In an example the end portions include solderable metallurgy. The angles of the extension sections with the middle section of a conductor are depicted in FIGS. 1, 2, 3, 4, 5, and 8 as right angles to the middle section of the conductors, but acute and obtuse angles are acceptable. In further examples the angles can be different angles for different conductors in the structure. In still further examples, the angles for a first extension section and a second extension section to the middle section of a selected conductor can be different from one another.

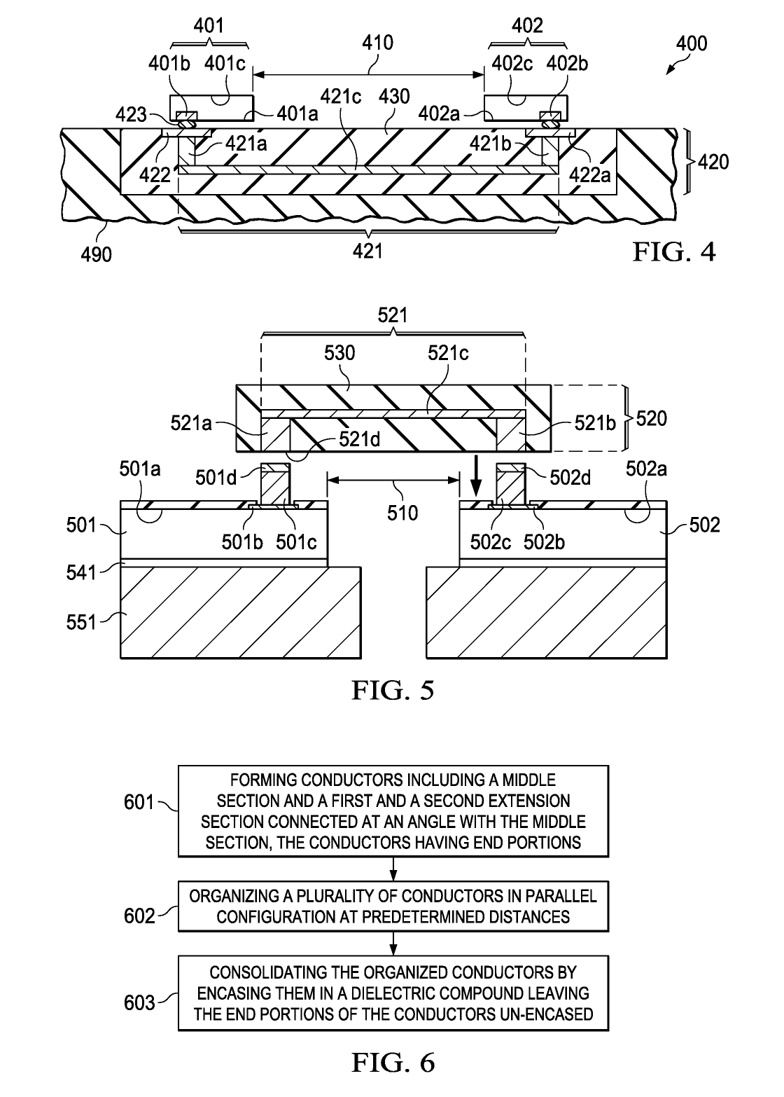

FIG. 4 is a cross section for another example arrangement for a device 400 using solder bumps and flip-chip technology. A first semiconductor die 401 and a second semiconductor die 402 are spaced from each other by a gap 410. Each die has a first surface (401a, 402a respectively) and an opposite second surface (401c, 402c respectively); the first surface of die 401 includes first terminals 401b of solderable metallurgy, the first surface of die 402 includes respective first terminals 402b. Each first terminal includes a bump, or ball, of solder 423, such as a tin alloy. The solder can be a lead free solder.

Device 400 includes a structure 420, which encompasses a plurality of conductors 421. The conductors 421 are embedded in a dielectric casing 430, which serves to consolidate the configuration and organization of the conductors 421. In FIG. 4, the conductors 421 have end portions 422 with a surface 422a un-embedded by casing 430 and thus exposed from the casing 430. In an example, surface 422a has solderable metallurgy. The solderable metallurgy can include a surface layer of tin or a stack of layers including a layer of nickel, a layer of palladium, and a layer of gold. In addition to the solderable metallurgy, end portions 422 can have a configuration different from the configuration of conductors 421; as an example, end portions 422 can have a larger diameter than conductors 421, as depicted in FIG. 4.

To connect the end portions 422 to the devices 401, 402, solder balls 423 are placed on the end terminals 422. Solder balls 423 are then subjected to a reflow process. An end portion 422 of each conductor 421 is soldered to a first terminal 401b of the first die 401, and the opposite end portion of each conductor 421 is soldered to respective first terminals 402b of the second die 402. In this fashion, first die 401 and second die 402 are flip-chip attached to conductors 421, and portions of conductors 421 extend across the gap 410 between the dies and conductively connect the first die and the second die. The flip-attached dies 401, 402 have active circuitry (not shown) on surfaces 401a, 402a, and are shown “flipped,” or face down, in the orientation of FIG. 4.

Analogous to the consideration above, the configuration of the conductors and the positioning of a plurality of conductors inside the dielectric casing 430 keeps stray capacitances within stable and acceptable limits. The process of fabricating a structure with fixed conductors includes the steps of forming wires into conductors 421. In an example the conductors may have a U-shaped cross section including a middle section 421c and a first (421a) and a second (421b) extension section connected at an angle with the middle section; the angles may be normal, acute, or obtuse angles. After organizing a plurality of conductors 421 in a desired configuration at predetermined distances, the organized conductors are consolidated by embedding them in a dielectric compound to form the structure. The structure 420 can be flexible and can appear similar to a plastic tape.

In the example of FIG. 4, structure 420 including a routing of conductors 421 inserted in a substrate 490 made of laminated layers. FIG. 4 shows structure 420 with its routing structure embedded in substrate 490, with dies 401 and 402 flip-attached onto structure 420. The second surfaces (401c, 402c respectively) of the dies 401, 402 face away from structure 420 and are available for further processing, such as attaching heat sinks. The assembly 400 can also be encapsulated using mold compound such as epoxy mold compound to form a packaged device.

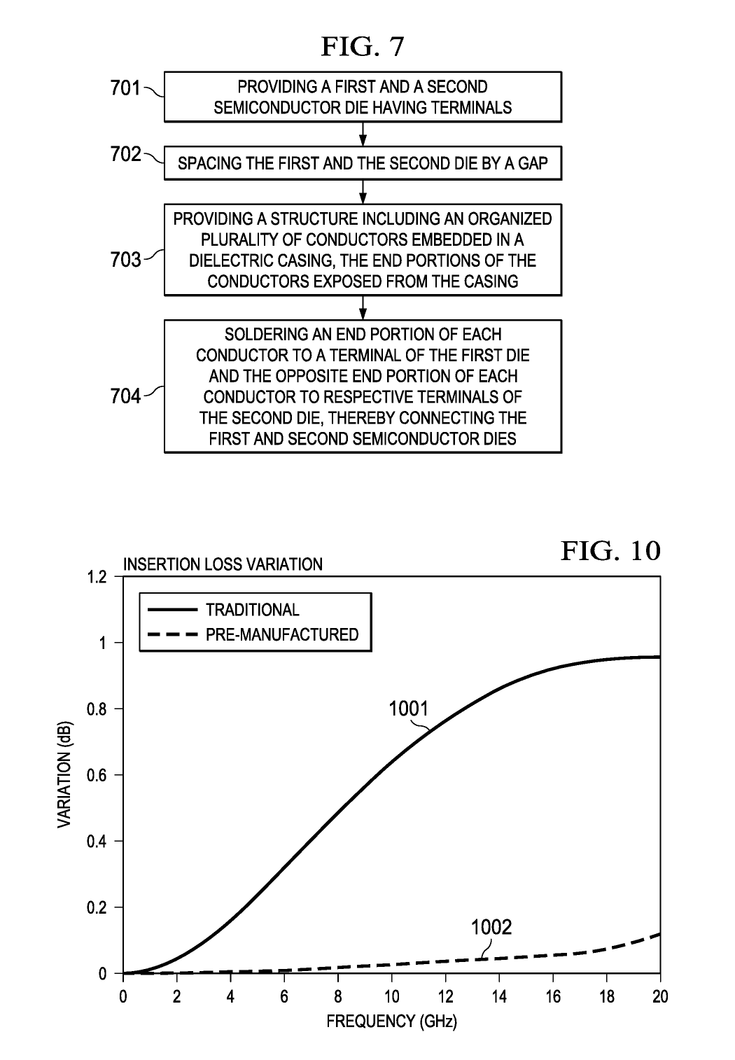

FIG. 5 is a cross section illustrating certain steps of a fabrication sequence described in conjunction with example process flows delineated in flow charts in FIGS. 6 and 7. Referring to FIG. 6, during step 601 of the process flow, conductive wires or strips are formed into conductors (see 521 in FIG. 5). The conductors 521 may be metallic wires or strips with uniform diameter throughout, or they may be composed of metal portions of different diameter, as shown in FIG. 5. A middle section 521c may have smaller diameter than a first extension section 521a and a second extension section 521b. The first and second extension sections can include solderable metallurgy. At least one of the extension sections may form a normal angle with the middle section; alternatively, acute or obtuse angles can be chosen to best fit the given geometries and to reduce or minimize stray and parasitic capacitances of the conductor.

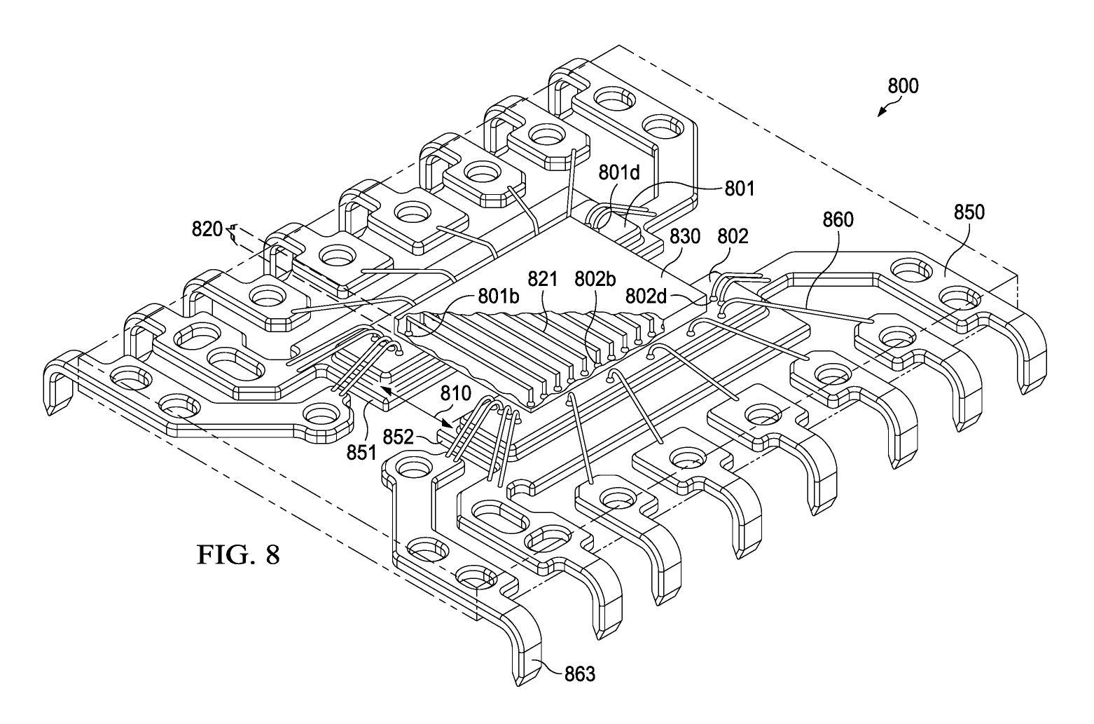

During step 602 of the process flow of FIG. 6, the conductors 521 (FIG. 5) are organized in terms of mutual spacing distances and parallelity so that stray and parasitic capacitances of the plurality of conductors are minimized. FIG. 8 described hereinbelow is a three dimensional view of an example arrangement 800 including an organized plurality of conductors 821 in a structure 820. Again referring to FIG. 6, in the next process step 603, these organized conductors are consolidated by encasing the conductors in a dielectric plastic compound (530 in FIG. 5). Because the structure 520 can be flexible and relatively thin, it can appear similar to a tape. A preferred plastic compound material is a polyimide compound. As commonly expressed, the plurality of conductors is frozen in the dielectric compound 520. Care is taken, however, to leave the end portions (521d in FIG. 5) of the conductors 521 un-encased for use in making connections to other components.

Referring now to the example method of the flow chart in FIG. 7, in step 701 of the process flow a first semiconductor die (501 in FIG. 5, for example) and a second semiconductor die (502 in FIG. 5) are provided that have at least one terminal. The terminals can include solderable metallurgy as described hereinabove. As the example arrangement of FIG. 5 illustrates, the surface 501a of first die 501 has a terminal structure so that the die metallization 501b is topped by a metallic pillar 501c, which in turn is topped by a solder cap 501d. As an example, metallization 501b and pillar 501c can be made of copper. In an analogous manner, the surface 502a of second die 502 has a terminal with a structure so that the die metallization 502b is topped by a metallic pillar 502c, which in turn is topped by a solder cap 502d. Solder caps 501d and 502d will reflow at the solder reflow temperature during the assembly process to connect to the solderable end portions of the conductors 521 of the structure 520. As shown in FIG. 5, the pillars 501c, 502c can be vertically bonded pillars or columns extending away from the surfaces 501a, 502a and having solder caps 501d, 502d.

Returning to FIG. 7, during step 702 of the process flow, first die (501 in FIG. 5) and second die (502 in FIG. 5) are positioned on pads 551 of a substrate so that they are spaced by gap 510. In an example arrangement, the positioning is achieved by a stable attachment to the pads using an adhesive layer 541. In an alternative arrangement, the positioning is achieved by a stable attachment using a solder layer 541.

During step 703 of the process flow of FIG. 7 and illustrated in FIG. 5, a structure 520 is provided, which includes an organized plurality of conductors 521 embedded in a dielectric casing 530. The process of fabricating such structure is described hereinabove with reference to FIG. 6; as pointed out, the end portions 521d of the conductors are exposed from the casing. The end portions 521d can include solderable metallurgy.

During step 704 of the process flow of FIG. 7 and as depicted in FIG. 5, an end portion 521d of a conductor is soldered to a terminal 501c of the first die 501, and the opposite end portion 521d of a conductor is soldered to a respective terminal 502c of the second die 502. As FIG. 5 shows, after completing the soldering process a portion of the structure 520 extends across the gap 510 spacing die 501 and die 502 and die 501 and die 502 are conductively connected. An example of a structure with a plurality of conductors consolidated in a dielectric casing is depicted as 820 in the arrangement of FIG. 8. The structure 820 has a portion that extends across the wide gap between two assembled semiconductor dies and the conductors in the structure 820 conductively connects the dies.

FIG. 8 illustrates in a projection view an example arrangement for a packaged device 800 including an embedded routing structure for capacitive isolation technology. Device 800 can be encapsulated in a molding compound such as a thermoplastic, a resin or other dielectric material. Lead ends of a leadframe 850 are left exposed and unencapsulated, forming leads 863 for making electrical contact to device 800 and for mounting the device 800 to a circuit board. A first semiconductor die 801, which can be a modulator, and a second semiconductor die 802, which can be a receiver, have first terminals (801b, 801b) for solder attachment and second terminals (801d, 802d) for wire ball bonding (see description hereinabove in conjunction with FIGS. 1, 2, and 3). The dies 801, 802 are assembled on rectangular pads 851 and 852, respectively, of a metallic leadframe 850 and are spaced from each other by gap 810. In various examples, the leadframe 850 can be etched or stamped from a thin sheet of base metal such as copper, copper alloy, iron-nickel alloy, aluminum, Kovar™, and others, in a typical thickness range from 120 to 250 μm. In addition to the first and second pads, the leadframe 850 of FIG. 8 offers a multitude of leads 863 to bring various electrical conductors into close proximity of the dies. The leads of leadframe 850 and the second terminals of the dies are connected by thin bonding wires 860.

Structure 820 depicted in FIG. 8 includes a plurality of conductors 821 configured and organized as tuned transmission lines and embedded in a dielectric casing 830 to consolidate the configuration. As mentioned above, the end portions of the conductors are un-embedded by the casing. The end portions of the conductors can include solderable metallurgy. The pre-determined and frozen shape (see additional cross section hereinabove) of the conductors and the parallel array of the conductors avoid high electrical field concentrations typically associated with ball bonds and stitch bonds in conventional wire bonding and any random wire kink and sagging related to bonding and packaging processes. As a consequence, electrical parasitics are minimized and stray resistances, inductances, and capacitances are under control. In a cross section the conductors 821 can have a U-shape or inverted U-shape.

As FIG. 8 shows, an end portion of the conductors 821 is soldered to a first terminal 801b of the first die 801, and the opposite end portion of the conductors is soldered to respective first terminals 802b of the second die 802. At least a portion of the conductors 821 of structure 820 extend across the gap 810, and physically and electrically connect the first die 801 and the second die 802.

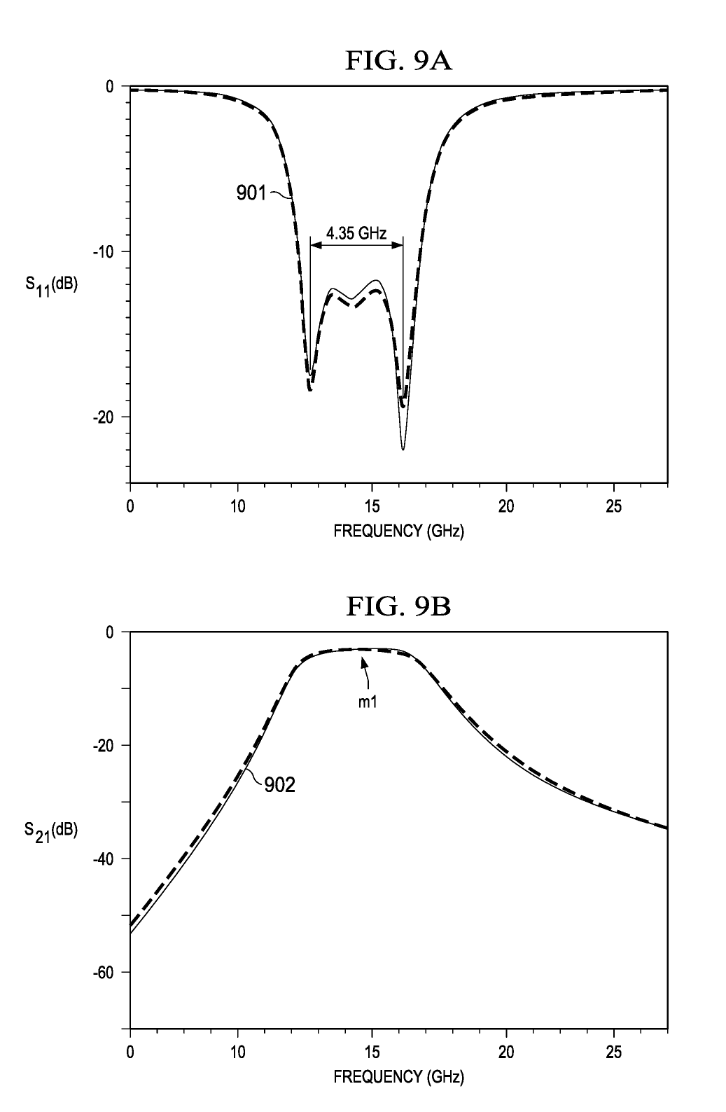

For high speed isolators, the advantage of using a pre-fabricated structure with predetermined conductors over conventional wire bonding is demonstrated by the modeling data displayed in FIGS. 9A, 9B, and 10. FIG. 9A displays the insertion loss S₁₁ (the ratio of reflected energy per incoming energy), expressed in dB, as a function of the frequency. Curve 901 shows that the loss drops to low values in a narrow pre-determined frequency band of about 4 GHz width. Stated inversely, the transmitted energy reaches high values in the same narrow pre-determined frequency band. Curve 902 depicts this correspondence in FIG. 9B, where the insertion loss S₂₁ (the ratio of transmitted energy per incoming energy), expressed in dB, is plotted as a function of the frequency, measured in GHz.

For devices in capacitive isolation technology, the overall variation of the insertion loss between transmitter die and receiver die is displayed as a function of frequency in FIG. 10. The data compare insertion losses as a function of frequency for devices using conventional wire bonding (curve 1001) for connecting the transmitter die across to the distantly spaced receiver die, with devices using pre-manufactured structures with embedded connectors (curve 1002) as routing structures for connecting the transmitter die across a gap to the distantly spaced receiver die. The data in FIG. 10 clearly demonstrate the superiority of the pre-manufactured structure with embedded connectors as routing structures for connecting transmitter and receiver dies across a spacing or gap.

Various modifications and combinations of the arrangements, as well as other alternative arrangements, are apparent upon reference to the description. As an example, in semiconductor technology, the arrangements apply not only to devices using solder as a connecting agent, but also to devices using conductive adhesive.

As another example, the arrangements apply not only to silicon-based semiconductor devices, but also to devices using gallium arsenide, gallium nitride, silicon germanium, and any other semiconductor material employed in industry.

As another example, the arrangements apply not only to devices using leadframes, but also to devices using laminated substrates and any other substrate or support structure.

Modifications are possible in the described arrangements, and other additional arrangements are possible, within the scope of the claims.

1-20. (canceled)

21. A device comprising:
a first object having a first terminal and a second object having a second terminal; and
at least one conductor in a dielectric casing, the at least one conductor including a middle section, a first extension section and a second extension section at opposing ends of the middle section, end portions of the first extension section and the second extension section exposed from the dielectric casing;
wherein diameters of the first extension section and the second extension section are different from a diameter of the middle section; and
wherein end portions of the first extension section and the second extension section electrically connected to the first terminal and the second terminal respectively.

22. The device of claim 21, wherein the first extension section and the second extension section are at an angle with respect to the middle section.

23. The device of claim 22, wherein the first extension section and the second extension section form right angles with the middle section.

24. The device of claim 21, wherein the dielectric casing includes an elastic polymeric compound.

25. The device of claim 21, wherein the first terminal of the first object and the first terminal of the second object include metallic pillars vertically bonded to the first and second objects, the metallic pillars capped by a solder layer.

26. The device of claim 21 further including a substrate onto which the second surfaces of the first object and of the second object are attached.

27. The device of claim 21, wherein the first object and the second object are selected from the group consisting of a semiconductor die, solid hexahedron-shaped carriers made of laminated plastic, and objects sensitive to electrical, magnetic, or optical influences.

28. An isolator comprising:
a first modulator semiconductor die and a second receiver semiconductor die, the first modulator semiconductor die and the second semiconductor die each having a first surface and an opposite second surface, the first surfaces including components and including first terminals; and
a first conductor in a first dielectric casing, the first conductor including a first section, a first extension section and a second extension section at opposing ends of the first section, end portions of the first extension section and the second extension section exposed from the dielectric casing;
wherein diameters of the first extension section and the second extension section are different from a diameter of the first section; and
wherein the end portion of the first extension is electrically connected to a first terminal of the first modulator semiconductor die, and the end portion of the second extension is electrically connected to a respective first terminal of the second receiver semiconductor die.

29. The isolator of claim 28, wherein the first modulator semiconductor die and the second receiver semiconductor die further include second terminals having metallurgy for wire bonding.

30. The isolator of claim 28 further including a metallic leadframe having pads and leads, the pads attached to the second surfaces of the first and second semiconductor dies.

31. The isolator of claim 30 further including bond wires connecting the second terminals to respective leads of the leadframe.

32. The isolator of claim 31, wherein the pads are at a plane parallel to a plane of surfaces attached to the bond wires.

33. The isolator of claim 31, wherein the plane of the pads are below the planes of the surfaces attached to the bond wires.

34. The isolator of claim 28, wherein the diameter of the first section is less that the diameters of the first extension section and the second extension section.

35. The isolator of claim 31 further including a package of an insulating compound, the package covering the first modulator semiconductor die, the second receiver semiconductor die, the dielectric casing, the bond wires, and at least portions of the leadframe and of the metallic leads, leaving residual portions of the metallic leads un-encapsulated.

36. The isolator of claim 28 further including a discrete isolation capacitor, the isolation capacitors having terminals electrically connected to a second conductor in a second dielectric casing, the second conductor including a first section, a first extension section and a second extension section at opposing ends of the first section.

37. The isolator of claim 28, wherein the end portion of the first extension is electrically connected to a first terminal of the first modulator semiconductor die, and the end portion of the second extension is electrically connected to the respective first terminal of the second receiver semiconductor die via a pad of copper with a surface of tin, or nickel/palladium, or nickel/palladium/gold.

38. A method for fabricating a device, comprising:
spacing a first object and a second object from each other by a gap, the first object and the second object each having a first surface and an opposite second surface, the first surfaces including first terminals;
forming conductors including a first section and a first extension section and a second extension section at opposing ends of the first section, the first extension section and the second extension section connected at an angle with the first section, wherein diameters of the first extension section and the second extension section are different from a diameter of the first section;
electrically connecting an end portion of at least one of the at least two conductors to a first terminal of the first object, and electrically connecting the opposite end portion of the at least one of the at least two conductors to a respective first terminal of the second object, that electrically connects the first and the second objects.

39. The method of claim 38, wherein forming conductors includes:
organizing the conductors in a parallel configuration at predetermined distances; and
embedding the conductors in a dielectric compound, the embedding leaving the end portions of the conductors un-embedded.

40. The method of claim 38, wherein the first object is a modulator of an isolator and which includes capacitors with terminals of solderable metallurgy, and the second object is a receiver of the isolator and includes capacitors with terminals of solderable metallurgy.
